(19) United States
(12) Patent Application Publication
(10) Pub. No.: US 2013/0313557 A1
(43) Pub. Date: Nov. 28, 2013

(54) DISPLAY APPARATUS

(71) Applicant: Sony Corporation, Tokyo (JP)

(72) Inventors: Yuichi Kato, Kanagawa (JP); Keiichi Akamatsu, Kanagawa (JP); Kenta Masuda, Kanagawa (JP)

(73) Assignee: Sony Corporation, Tokyo (JP)

(21) Appl. No.: 13/893,489

(22) Filed: May 14, 2013

(30) Foreign Application Priority Data
May 21, 2012 (JP) 2012-115358

(51) Int. Cl. H01L 27/105

(52) U.S. Cl. CPC H01L 27/105
USPC 257/59; 257/71

(57) ABSTRACT

A display apparatus includes a scanning line to which a scanning signal is input, a signal line arranged perpendicular to the scanning line to which an image signal is input, a storage capacity line arranged in parallel with the signal line, an insulating film having a gate insulating portion that covers a gate electrode of a transistor, a pixel electrode connected to the transistor, a capacitor including a first electrode and a second electrode, the first electrode connected to the storage capacity line, the second electrode connected to the pixel electrode, and a protection film having a first insulating portion and a second insulating portion, the first insulating portion covering a source electrode and a drain electrode, the second insulating portion provided between the first electrode and the second electrode, the first electrode and the second electrode arranged to face each other with the second insulating portion disposed therebetween.

### BACKGROUND

The present disclosure relates to a technical field of a display apparatus. Specifically, the present disclosure relates to a technical field in which the storage capacitance of a capacitor is increased while achieving the uniform storage capacitance by arranging a first electrode and a second electrode of the capacitor to face each other with a protection film, which is different from an insulating film having a gate insulating portion, disposed therebetween.

As a display apparatus using a display unit such as an electrophoretic display, a liquid crystal display, and an organic EL (Electro Luminescence) display, various display apparatuses such as a television receiver, a personal computer, a monitor, a cellular phone, and a tablet terminal are developed or commercialized.

In particular, in recent years, also a display apparatus such as an electronic book in which information on, for example, the content of a book is displayed on a display is widely used.

Such a display includes a scanning line and a signal line, which are arranged on a glass substrate or a plastic substrate in a matrix pattern, a pixel electrode arranged in a portion between the scanning line and the signal line, a storage capacity line arranged in parallel with the scanning line, and the like. At a portion where the scanning line and the signal line intersect with each other, a thin film transistor (TFT) functioning as a switching element is provided. Between a gate electrode, which is connected to the scanning line, and a source electrode and a drain electrode, which are connected to the signal line, an insulating film (a gate insulating film) is provided.

A portion of the display on which the scanning line, the signal line, the transistor are provided is provided as a transistor layer. For example, in the electrophoretic display, a plurality of electrophoretic elements are tightly arranged in a matrix pattern between a pixel electrode of the transistor layer and an opposing electrode being a surface layer. The electrophoretic element is formed as a transparent microcapsule in which a positively charged white pigment and negatively charged black pigment as well as oil are contained.

The transistor layer is formed through a series of lithography processes, i.e., repeated processes of deposition, photoresist application, exposition, development, etching, and removal of the photoresist.

In the above-mentioned display, a capacitor for suppressing the leakage of direct current and the effect of transient current during electrophoresis is provided. The capacitor includes a first electrode connected to a storage capacity line and a second electrode connected to a drain electrode of a thin film transistor, which are arranged to face each other with the above-mentioned insulating film (gate insulating film) disposed therebetween. In forming the transistor layer, the scanning line, the signal line, and the transistor are provided on a predetermined portion of the transistor layer, and the capacitor can be formed in the other portions (areas).

There is a need to provide, on the display, the above-mentioned capacitor for holding charges. However, in order to cause the display to appropriately operate by suppressing the leakage of direct current and the effect of transient current, the capacitor needs a sufficient storage capacitance. Therefore, it is desirable to increase the storage capacitance. In the electrophoretic display, the cell gap, i.e., the thickness of a display layer on which an electrophoretic element is arranged, is larger than that in the liquid crystal display. Therefore, in order to suppress the leakage of direct current and the generation of transient current, it is particularly necessary to increase the storage capacitance of the capacitor.

However, since the capacitor is provided in a portion other than a portion where the scanning line, the signal line, and the transistor are provided, if the size (area) of the capacitor is increased to increase the storage capacitance, the size of the entire display is increased, which disturbs the size reduction of the display apparatus. Therefore, in order to increase the storage capacitance of the capacitor while achieving the size reduction of the display apparatus, there is a need to increase the storage capacitance per unit area.

On the other hand, the transistor layer is favorably small, because capacitance called cross capacitance, which is generated at a portion where the scanning line and the signal line intersect with each other, can cause delay of an electric signal in the scanning line or the signal line. Therefore, if the thickness of the insulating film provided between the gate electrode that is connected to the scanning line and the source electrode that is connected to the signal line is increased in order to decrease the cross capacitance, the distance between the first electrode and the second electrode of the capacitor is increased, thereby decreasing the storage capacitance.

In this regard, in order to decrease the cross capacitance and increase the storage capacitance of the capacitor, some existing display apparatuses include an insulating film having a two-layered configuration, which includes a first insulating film and a second insulating film excluding a portion thereof (e.g., see Japanese Patent Application Laid-open No. 2011-164303).

In the display apparatus described in Japanese Patent Application Laid-open No. 2011-164303, a first insulating film and a second insulating film are provided in a state of being laminated between a gate electrode of a transistor and source and drain electrodes of the transistor, an opening is formed on the first insulating film that is located between a first electrode and a second electrode of a capacitor, and the second insulating film is provided on the opening, thereby decreasing the thickness of the insulating film.

Therefore, an insulating film having a two-layered configuration is provided between the gate electrode and the source electrode and the drain electrode, thereby decreasing the cross capacitance. An insulating film having a single-layered configuration is provided between the first electrode and the second electrode of the capacitor, thereby increasing the storage capacitance.

### SUMMARY

However, since the display apparatus described in Japanese Patent Application Laid-open No. 2011-164303 includes an insulating film having a two-layered configuration of the first insulating film and the second insulating film, in a process of forming the insulating film, there is a need to perform processes of deposition, patterning, etching, and further deposition.

Therefore, it is difficult to form the insulating film to have a uniform thickness, and the uniform storage capacitance of the capacitor may not be achieved.

In view of the above-mentioned circumstances, it is desirable to provide a display apparatus that is capable of solving the above-mentioned problems, and increasing the storage capacitance while achieving the uniform storage capacitance of the capacitor.

First, according to an embodiment of the present disclosure, there is provided a display apparatus including:

a scanning line to which a scanning signal is input;

a signal line to which an image signal is input and which is arranged perpendicular to the scanning line;

a storage capacity line arranged in parallel with the signal line;

an insulating film having a gate insulating portion that covers a gate electrode of a transistor;

a pixel electrode connected to the transistor;

a capacitor including a first electrode and a second electrode, the first electrode being connected to the storage capacity line, the second electrode being connected to the pixel electrode;

a protection film having a first insulating portion and a second insulating portion, the first insulating portion covering a source electrode and a drain electrode of the transistor, the second insulating portion being provided between the first electrode and the second electrode, the first electrode and the second electrode being arranged to face each other with the second insulating portion of the protection film disposed therebetween.

Therefore, in the display apparatus, the gate insulating portion and the second insulating portion are provided as different insulating layers.

Second, in the above-mentioned display apparatus, it is desirable that the second insulating portion of the protection film has a thinner thickness than the gate insulating portion of the insulating film.

Since the second insulating portion of the protection film has a thinner thickness than the gate insulating portion of the insulating film, the storage capacitance of the capacitor is increased without increasing the cross capacitance that is generated at a portion where the scanning line and the signal line intersect with each other.

Third, in the above-mentioned display apparatus, it is desirable that the protection film has a higher dielectric constant than the insulating film.

Since the protection film has a higher dielectric constant than the insulating film, the storage capacitance of the capacitor is increased without increasing the cross capacitance that is generated at a portion where the scanning line and the signal line intersect with each other.

Fourth, in the above-mentioned display apparatus, it is desirable that a third electrode is provided to the capacitor, the third electrode being connected to the transistor and located on an opposite side of the first electrode with the insulating film disposed therebetween.

Since a third electrode is provided to the capacitor, the third electrode being connected to the transistor and located on an opposite side of the first electrode with the insulating film disposed therebetween, the capacitor includes the three electrodes, and the protection film and the insulating film, which are provided between the three electrodes.

Fourth, in the above-mentioned display apparatus, it is desirable that a planarization film is provided between the pixel electrode and at least the first insulating portion of the protection film, a concave portion is formed on the planarization film, and the second electrode of the capacitor is provided on a bottom surface of the concave portion.

Since a planarization film is provided between the pixel electrode and at least the first insulating portion of the protection film, a concave portion is formed on the planarization film, and the second electrode of the capacitor is provided on a bottom surface of the concave portion, the second electrode is provided at a portion where the planarization film does not exist.

A display apparatus according to an embodiment of the present disclosure includes:

a scanning line to which a scanning signal is input;

a signal line to which an image signal is input and which is arranged perpendicular to the scanning line;

a storage capacity line arranged in parallel with the signal line;

an insulating film having a gate insulating portion that covers a gate electrode of a transistor;

a pixel electrode connected to the transistor;

a capacitor including a first electrode and a second electrode, the first electrode being connected to the storage capacity line, the second electrode being connected to the pixel electrode; and

a protection film having a first insulating portion and a second insulating portion, the first insulating portion covering a source electrode and a drain electrode of the transistor, the second insulating portion being provided between the first electrode and the second electrode, the first electrode and the second electrode being arranged to face each other with the second insulating portion of the protection film disposed therebetween.

Therefore, the protection film can be formed to have a uniform thickness without being influenced by the formation of the insulating film, and it is possible to increase the storage capacitance while achieving the uniform storage capacitance of the capacitor.

In the display apparatus according to the embodiment of the present disclosure, the second insulating portion of the protection film has a thinner thickness than the gate insulating portion of the insulating film.

Therefore, the storage capacitance of the capacitor can be increased without increasing the cross capacitance that is generated at a portion where the scanning line and the signal line intersect with each other, and it is possible to prevent delay of an electric signal and to cause the display apparatus to appropriately operate.

In the display apparatus according to the embodiment of the present disclosure, the protection film has a higher dielectric constant than the insulating film.

Therefore, the storage capacitance of the capacitor can be increased without increasing the cross capacitance that is generated at a portion where the scanning line and the signal line intersect with each other, and it is possible to prevent delay of an electric signal and to cause the display apparatus to appropriately operate.

In the display apparatus according to the embodiment of the present disclosure, a third electrode is provided to the capacitor, the third electrode being connected to the transistor and located on an opposite side of the first electrode with the insulating film disposed therebetween.

Therefore, it is possible to further increase the storage capacitance.

In the display apparatus according to the embodiment of the present disclosure, a planarization film is provided between the pixel electrode and at least the first insulating portion of the protection film, a concave portion is formed on the planarization film, and the second electrode of the capacitor is provided on a bottom surface of the concave portion.

Therefore, it is possible to easily form the second electrode of the capacitor, which is connected to the pixel electrode.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 shows a display apparatus according to an embodiment of the present disclosure similarly to FIG. 2 to FIG. 10, and is a schematic perspective view of the display apparatus;

FIG. 2 is a schematic enlarged plan view showing a transistor layer of a display;

FIG. 3 is an enlarged cross-sectional view of the display taken along the line III-III of FIG. 2;

FIG. 4 shows a state in a process of manufacturing the display similarly to FIG. 5 to FIG. 8, and is an enlarged cross-sectional view showing a state in which a scanning line is formed on a base plate;

FIG. 5 is an enlarged cross-sectional view showing a state in which a storage capacity line is formed on an insulating film, a semiconductor is mounted on the insulating film, and a signal line and a connection line are formed;

FIG. 6 is an enlarged cross-sectional view showing a state in which a protection film is formed on the insulating film;

FIG. 7 is an enlarged cross-sectional view showing a state in which a planarization film is formed on the protection film;

FIG. 8 is an enlarged cross-sectional view showing a state in which a pixel electrode is formed on the planarization film;

FIG. 9 is an enlarged cross-sectional view showing an example in which a capacitor including three electrodes is provided; and

FIG. 10 is an enlarged cross-sectional view showing an example in which a surface of an adhesive layer on the side of a display layer is formed to be flat.

### DETAILED DESCRIPTION OF EMBODIMENTS

Hereinafter, embodiments according to the present disclosure will be described with reference to the accompanying drawings.

A display apparatus according to an embodiment of the present disclosure is applied to a display apparatus, which includes an electrophoretic display as a display and has a function as a tablet terminal such as an electronic book.

The display apparatus according to the embodiment is not limited to the display apparatus, which includes an electrophoretic display and has a function as a tablet terminal such as an electronic book. The display apparatus according to the embodiment may be widely applied to a display apparatus including another kind of display such as a liquid crystal display and an organic EL (Electro Luminescence) display, and also to various display apparatuses such as a tablet terminal other than the electronic book, a television receiver, a personal computer, a monitor, a cellular phone, and an imaging apparatus, e.g., a camera, which include a display

### [Schematic Configuration of Display Apparatus]

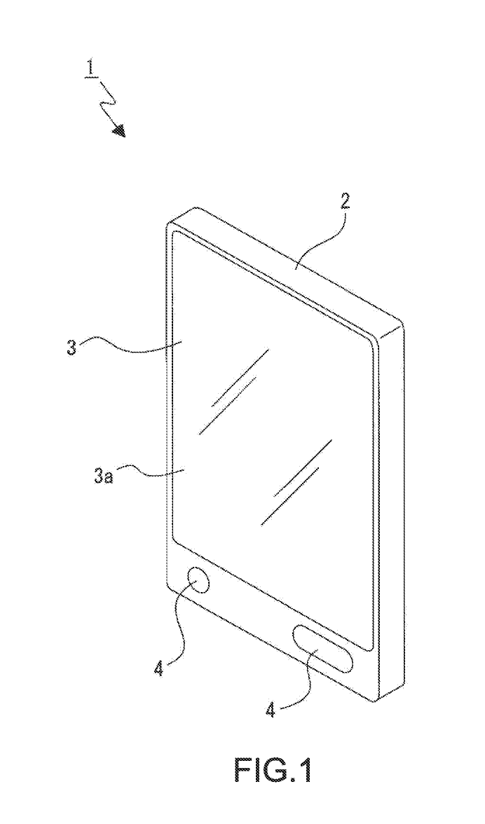

Hereinafter, the schematic configuration of the display apparatus will be described (see FIG. 1).

A display apparatus 1 is, for example, a tablet terminal such as an electronic book, and includes a thin casing 2 and a display 3 supported by the casing 2.

On the casing 2, various operation units 4, 4, . . . are arranged. By operating the operation units 4, 4, . . . , various operations such as turning on and off of a power supply, switching of a mode, displaying a screen on the display 3, and changing the screen are performed.

The display 3 is, for example, an electrophoretic display, and the front surface thereof is formed as a display surface 3a.

### [Specific Configuration of Display]

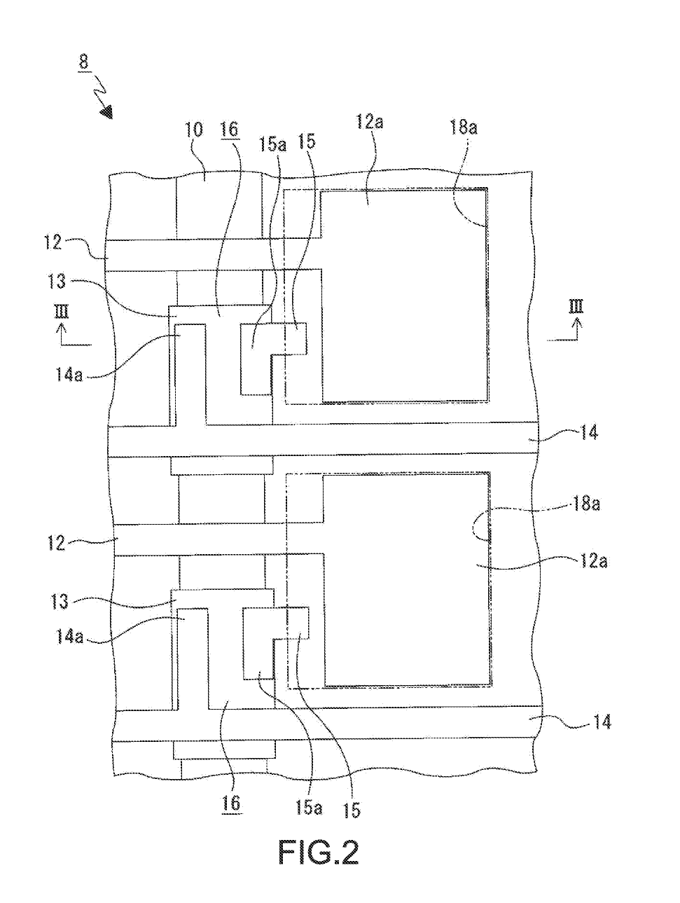

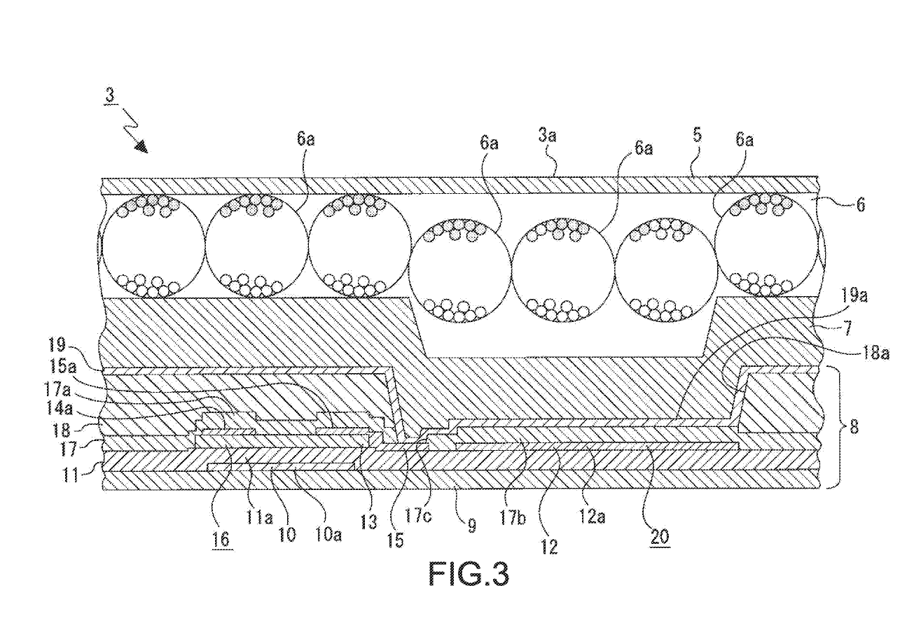

Next, the specific configuration of the display 3 will be described (see FIG. 2 and FIG. 3).

The display 3 includes an electrode layer 5, a display layer 6, an adhesive layer 7, and a transistor layer 8, which are laminated in the stated order in the thickness direction (see FIG. 3).

The electrode layer 5 includes a surface layer (cover layer) and an ITO layer (transparent electrode layer) laminated on the inner surface of the surface layer.

The display layer 6 includes a plurality of microcapsules 6a, 6a, . . . , which are tightly arranged in a matrix pattern. The microcapsule 6a functions as an electrophoretic element, and includes, for example, black and white pigment particles as well as oil. The white pigment particle is positively charged and the black pigment particle is negatively charged.

The adhesive layer 7 bonds the display layer 6 to the transistor layer 8, and is formed by a predetermined adhesive.

The transistor layer 8 includes predetermined components provided in a state of being laminated on a base plate 9 that includes a glass material or a plastic material (see FIG. 2 and FIG. 3).

On the base plate 9, a scanning line 10, which extends in a predetermined direction, is arranged. To the scanning line 10, a gate electrode 10a is connected. On the base plate 9, an insulating film 11 is laminated. A portion of the insulating film 11, which covers the gate electrode 10a, is provided as a gate insulating portion 11a.

On the insulating film 11, a storage capacity line 12 is arranged, and the storage capacity line 12 is provided perpendicular to the scanning line 10. To the storage capacity line 12, a first electrode 12a is connected. Moreover, on the insulating film 11, a semiconductor 13 is arranged on an opposite side of the gate electrode 10a with the gate insulating portion 11a disposed therebetween.

On the insulating film 11, a signal line 14 is arranged, and the signal line 14 is provided perpendicular to the scanning line 10. To the signal line 14, a source electrode 14a is connected, and the source electrode 14a is connected to one surface of the semiconductor 13. Moreover, on the insulating film 11, a connection line 15 is arranged. To the connection line 15, a drain electrode 15a is connected. The drain electrode 15a is connected to one surface of the semiconductor 13 to be located lateral to the source electrode 14a.

As described above, the semiconductor 13 is arranged on an opposite side of the gate electrode 10a with the gate insulating portion 11a disposed therebetween, and the source electrode 14a and the drain electrode 15a are connected to one surface of the semiconductor 13, thereby forming a transistor (thin film transistor) 16.

On the insulating film 11, a protection film 17 is laminated. The protection film 17 convers the storage capacity line 12, the semiconductor 13, the signal line 14, and the connection line 15. A portion of the protection film 17, which covers the source electrode 14a and the drain electrode 15a, is provided as a first insulating portion 17a. A portion of the protection film 17, which covers the first electrode 12a, is provided as a second insulating portion 17b. On the protection film 17, a communication hole 17c that communicates with a portion of the connection line 15 is formed.

The protection film 17 includes, for example, a material that is different from that of the insulating film 11, and has a higher dielectric constant than the insulating film 11. It should be noted that the protection film 17 may include the same material as that of the insulating film 11. In this case, the second insulating portion 17b has a thinner thickness than the gate insulating portion 11a. Moreover, the protection film 17 may include a material that is different from that of the insulating film 11, have a higher dielectric constant than the insulating film 11, and the second insulating portion 17b may have a thinner thickness than the gate insulating portion 11a

On the protection film 17, a planarization film 18 is laminated excluding a portion of the second insulating portion 17b. As described above, since the planarization film 18 is laminated on the protection film 17 excluding a portion of the second insulating portion 17b, a concave portion 18a is formed on a portion of the planarization film 18, which corresponds to the second insulating portion 17b.

On the planarization film 18, a pixel electrode 19 is arranged. To the pixel electrode 19, a second electrode 19a, which is arranged on the second insulating portion 17b, is connected. Therefore, the second electrode 19a is located on a bottom surface of the concave portion 18a, and the second electrode 19a and the first electrode 12a are arranged to face each other with the second insulating portion 17b disposed therebetween. A capacitor 20 includes the first electrode 12a, the second insulating portion 17b, and the second electrode 19a.

The pixel electrode 19 is connected to the drain electrode 15a that is connected to the connection line 15 via the concave portion 18a and the communication hole 17c.

As described above, in the display 3, the concave portion 18a is formed on the planarization film 18, and the second electrode 19a, which is included in the capacitor 20, is provided on a bottom surface of the concave portion 18a.

As described above, in the display 3, the concave portion 18a is formed on the planarization film 18, and the second electrode 19a is provided on the concave portion 18a. Therefore, it is possible to easily form the second electrode 19a, which is connected to the pixel electrode 19 and is included in the capacitor 20.

### [Operation of Display]

In the display 3 configured as described above, if a drive current is supplied from a control circuit (not shown) and an electric field is generated between the electrode layer 5 and the pixel electrode 19, the black and white pigment particles in the plurality of microcapsules 6a, 6a, . . . , which are arranged in the display layer 6, move in oil. At this time, the black pigment particle or the white pigment particle aggregates on the side of the electrode layer 5 in the microcapsules 6a, 6a, . . . by negative or positive voltage, thereby displaying black or white color.

### [Process of Manufacturing Display]

Next, the process of manufacturing the display 3 will be described (see FIG. 3 to FIG. 8). It should be noted that the display 3 is manufactured through a series of lithography processes, i.e., repeated processes of deposition, photoresist application, exposition, development, etching, and removal of the photoresist.

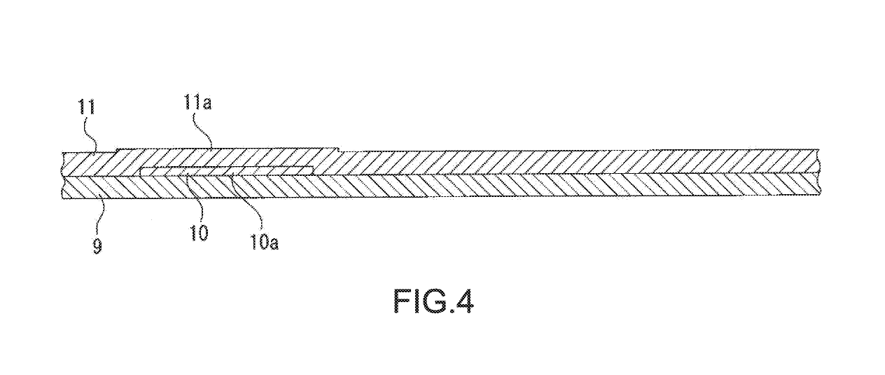

First, the scanning line 10 is formed on the base plate 9, and the insulating film 11 is laminated thereon so as to cover the scanning line 10 (see FIG. 4). When the scanning line 10 is formed, also the gate electrode 10a is formed.

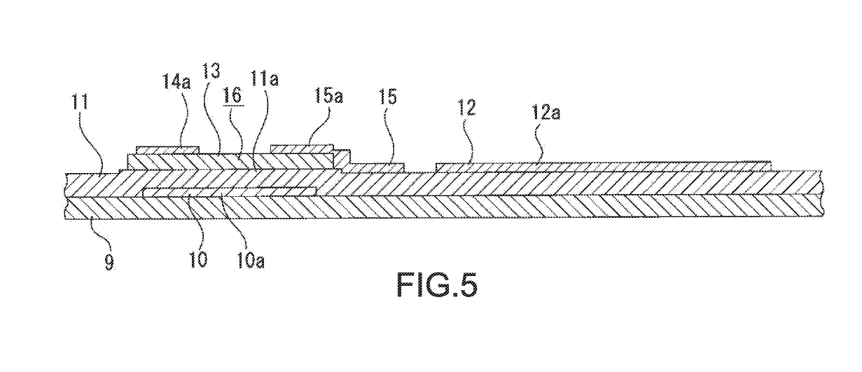

Next, the storage capacity line 12 is formed on the insulating film 11, the semiconductor 13 is mounted on the insulating film 11, and the signal line 14 and the connection line 15 are formed (see FIG. 5). At this time, the storage capacity line 12 is not connected to the connection line 15. When the storage capacity line 12 is formed, also the first electrode 12a is formed. When the signal line 14 and the connection line 15 are formed, also the source electrode 14a and the drain electrode 15a are formed, respectively.

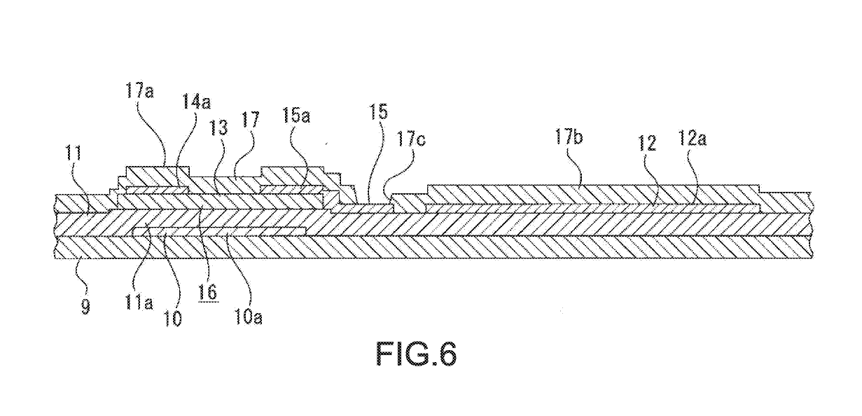

Next, the protection film 17 is formed on the insulating film 11 (see FIG. 6). At this time, the communication hole 17c, which communicates with the connection line 15, is formed on the protection film 17.

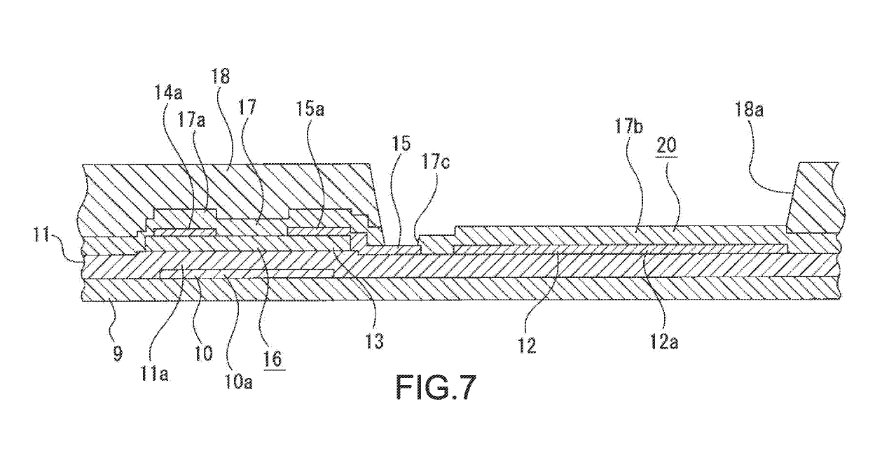

Next, the planarization film 18 is formed on the protection film 17 (see FIG. 7). At this time, the concave portion 18a is formed on a portion of the planarization film 18, which corresponds to the second insulating portion 17b. The concave portion 18a communicates with the communication hole 17c.

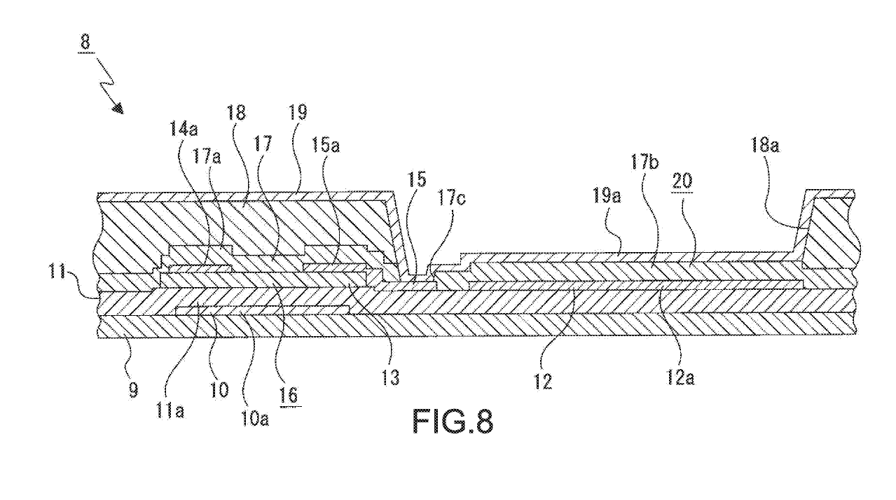

Next, the pixel electrode 19 is formed on the planarization film 18 (see FIG. 8). At this time, a portion of the pixel electrode 19 is formed on the communication hole 17c, and the pixel electrode 19 is connected to the drain electrode 15a, which is connected to the connection line 15. When the pixel electrode 19 is formed, also the second electrode 19a is formed.

Next, the adhesive layer 7, the display layer 6, and the electrode layer 5 are formed in the stated order. Thus, the display 3 is manufactured (see FIG. 3).

### [Summary]

As described above, in the display apparatus 1, the capacitor 20 including the first electrode 12a connected to the storage capacity line 12 and the second electrode 19a connected to the pixel electrode 19 is formed, and the first electrode 12a and the second electrode 19a are arranged to face each other with the protection film 17, which is different from the insulating film 11, disposed therebetween.

Therefore, the protection film 17 can be formed to have a uniform thickness without being influenced by the formation of the insulating film 11, and it is possible to increase the storage capacitance while achieving the uniform storage capacitance of the capacitor 20.

Moreover, in the display 3, a film of the transistor 16 is different from that of the capacitor 20, i.e., the transistor 16 includes the insulating film 11 and the capacitor 20 includes the protection film 17. Therefore, as described above, the second insulating portion 17b of the protection film 17 can have a thinner thickness than the gate insulating portion 11a of the insulating film 11.

As described above, since the second insulating portion 17b has a thinner thickness than the gate insulating portion 11a, the storage capacitance of the capacitor 20 can be increased without increasing the cross capacitance generated at a portion where the scanning line 10 and the signal line 14 intersect with each other, and it is possible to prevent delay of an electric signal and to cause the display apparatus 1 to appropriately operate.

Furthermore, in the display 3, since a film of the transistor 16 is different from that of the capacitor 20, i.e., the transistor 16 includes the insulating film 11 and the capacitor 20 includes the protection film 17, as described above, the protection film 17 can have a higher dielectric constant than the insulating film 11.

As described above, since the protection film 17 has a higher dielectric constant than the insulating film 11, the storage capacitance of the capacitor 20 can be increased without increasing the cross capacitance generated at a portion where the scanning line 10 and the signal line 14 intersect with each other, and it is possible to prevent delay of an electric signal and to cause the display apparatus 1 to appropriately operate.

### [Other Examples]

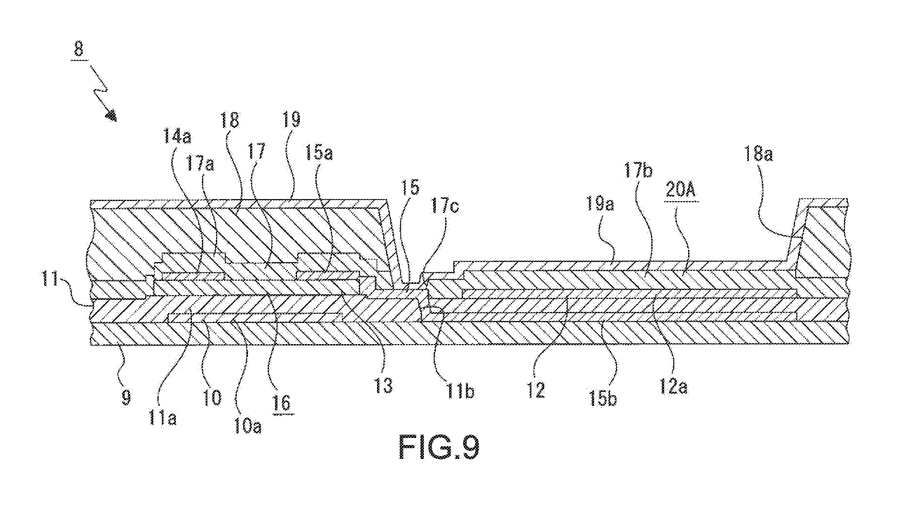

In the description above, the capacitor 20, which includes the first electrode 12a and the second electrode 19a, is provided. However, it is possible to provide, for example, a capacitor 20A, which includes three electrodes, i.e., a third electrode 15b in addition to the first electrode 12a and the second electrode 19a (see FIG. 9).

The third electrode 15b is arranged on the base plate 9, is covered by the insulating film 11 while being connected to the connection line 15 via a connection hole 11b that is formed on the insulating film 11, and is arranged to face the first electrode 12a with the insulating film 11 disposed therebetween.

As described above, the capacitor 20A is formed by providing the third electrode 15b that is arranged to face the first electrode 12a with the insulating film 11 disposed therebetween. Therefore, it is possible to further increase the storage capacitance.

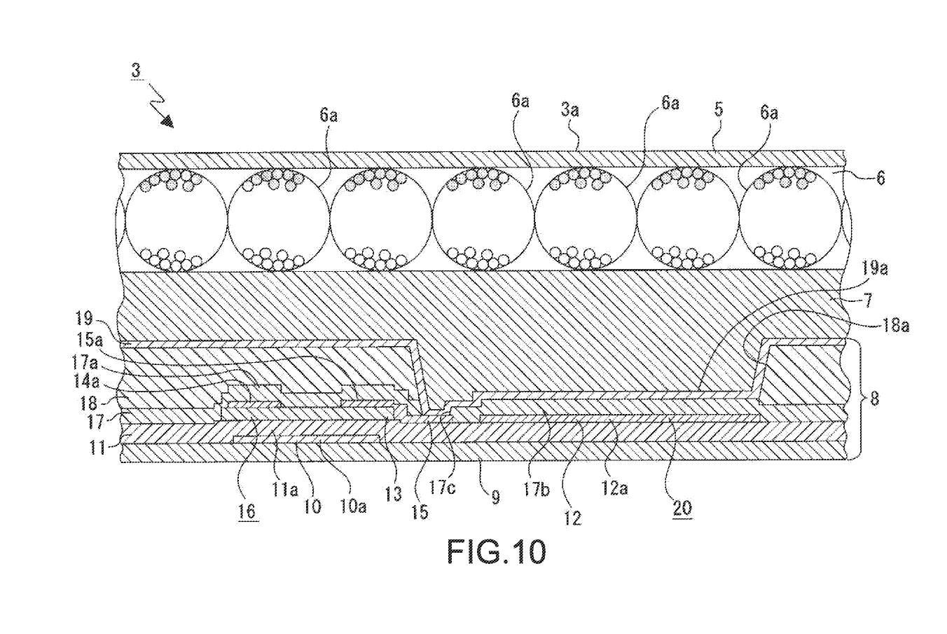

Moreover, in the description above, as shown in FIG. 3, a concave portion is formed on also the adhesive layer 7 by the concave portion 18a formed on the planarization film 18. However, as shown in FIG. 10, a portion where the adhesive is filled in the concave portion 18a can have a thicker thickness than other portions, thereby forming the surface of the adhesive layer 7 on the side of the display layer 6 to be flat.

As described above, since the surface of the adhesive layer 7 on the side of the display layer 6 is formed to be flat, the display layer 6 can have a uniform thickness, and the microcapsules 6a, 6a, . . . , which are arranged in the display layer 6, can be arranged at the same location in the thickness direction.

It should be noted that a portion where the adhesive is filled in the concave portion 18a can have a thicker thickness than other portions, thereby forming the surface of the adhesive layer 7 on the side of the display layer 6 to be flat, similarly to the case where the capacitor 20A instead of the capacitor 20 is provided.

### [Present Disclosure]

It should be noted that the present disclosure may also take the following configurations.

(1) A display apparatus, including:

a scanning line to which a scanning signal is input;

a signal line to which an image signal is input and which is arranged perpendicular to the scanning line;

a storage capacity line arranged in parallel with the signal line;

an insulating film having a gate insulating portion that covers a gate electrode of a transistor;

a pixel electrode connected to the transistor;

a capacitor including a first electrode and a second electrode, the first electrode being connected to the storage capacity line, the second electrode being connected to the pixel electrode; and

a protection film having a first insulating portion and a second insulating portion, the first insulating portion covering a source electrode and a drain electrode of the transistor, the second insulating portion being provided between the first electrode and the second electrode, the first electrode and the second electrode being arranged to face each other with the second insulating portion of the protection film disposed therebetween.

(2) The display apparatus according to (1), in which

the second insulating portion of the protection film has a thinner thickness than the gate insulating portion of the insulating film.

(3) The display apparatus according to (1) or (2), in which

the protection film has a higher dielectric constant than the insulating film.

(4) The display apparatus according to any one of (1) to (3), in which

a third electrode is provided to the capacitor, the third electrode being connected to the transistor and located on an opposite side of the first electrode with the insulating film disposed therebetween.

(5) The display apparatus according to any one of (1) to (4), in which

a planarization film is provided between the pixel electrode and at least the first insulating portion of the protection film,

a concave portion is formed on the planarization film, and

the second electrode of the capacitor is provided on a bottom surface of the concave portion.

It should be noted that the specific shapes and configurations of the components shown in the embodiments described above are only examples for embodying the present disclosure and do not limit the scope of the present disclosure.

The present disclosure contains subject matter related to that disclosed in Japanese Priority Patent Application JP 2012-115358 filed in the Japan Patent Office on May 21, 2012, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display apparatus, comprising:
a scanning line to which a scanning signal is input;
a signal line to which an image signal is input and which is arranged perpendicular to the scanning line;
a storage capacity line arranged in parallel with the signal line;
an insulating film having a gate insulating portion that covers a gate electrode of a transistor;
a pixel electrode connected to the transistor;
a capacitor including a first electrode and a second electrode, the first electrode being connected to the storage capacity line, the second electrode being connected to the pixel electrode; and
a protection film having a first insulating portion and a second insulating portion, the first insulating portion covering a source electrode and a drain electrode of the transistor, the second insulating portion being provided between the first electrode and the second electrode, the first electrode and the second electrode being arranged to face each other with the second insulating portion of the protection film disposed therebetween.

2. The display apparatus according to claim 1, wherein
the second insulating portion of the protection film has a thinner thickness than the gate insulating portion of the insulating film.

3. The display apparatus according to claim 1, wherein
the protection film has a higher dielectric constant than the insulating film.

4. The display apparatus according to claim 1, wherein
a third electrode is provided to the capacitor, the third electrode being connected to the transistor and located on an opposite side of the first electrode with the insulating film disposed therebetween.

5. The display apparatus according to claim 1, wherein
a planarization film is provided between the pixel electrode and at least the first insulating portion of the protection film,
a concave portion is formed on the planarization film, and
the second electrode of the capacitor is provided on a bottom surface of the concave portion.
